(19) United States
(12) Patent Application Publication
(10) Pub. No.: US 2006/0286706 A1
(43) Pub. Date: Dec. 21, 2006

(54) Method of making a substrate contact for a capped MEMS at the package level

(76) Inventors: Arvind S. Salian, Chandler, AZ (US); Hemant D. Desai, Gilbert, AZ (US); Stephen R. Hooper, Mesa, AZ (US); William G. McDonald, Scottsdale, AZ (US)

Correspondence Address: INGRASSIA, FISHER & LORENZ, P.C., 7150 E. CAMELBACK ROAD, SUITE 325, SCOTTSDALE, AZ, 85251, US

(21) Appl. No.: 11/158,795

(22) Filed: Jun. 21, 2005

(51) Int. Cl. H01L 21/00

(52) U.S. Cl. 438/50; 438/51

(57) ABSTRACT

Methods have been provided for forming a micro-electromechanical systems (“MEMS”) device (100) from a substrate (500) comprising a handle layer (108) and a cap (132) overlying the handle layer (108). In one exemplary embodiment, the method includes cutting through the substrate (500) to separate the substrate (500) into a first die (148) and a second die (150), the first die (148) having a first sidewall (138), and depositing a conductive material (182) onto the first sidewall (138) to electrically couple the cap (132) to the handle layer (108).

### FIELD OF THE INVENTION

The present invention generally relates to micro-electromechanical systems (“MEMS”), and more particularly relates to establishing a contact for use on MEMS.

### BACKGROUND OF THE INVENTION

Many devices and systems include a number of different types of sensors that perform various monitoring and/or control functions. Advancements in micromachining and other microfabrication processes have enabled the manufacturing of a wide variety of microelectromechanical systems (“MEMS”) devices. In recent years, many of the sensors that are used to perform monitoring and/or control functions have been implemented into MEMS devices.

One particular type of MEMS sensor is an accelerometer. Typically, a MEMS accelerometer includes, among other component parts, a proof mass that may be constructed on a silicon-on-insulator wafer. The proof mass is resiliently suspended by one or more suspension springs to one section of the wafer. The proof mass moves when the MEMS accelerometer experiences acceleration, and the movement is converted into an electrical signal having a parameter magnitude (e.g., voltage, current, frequency, etc.) that is proportional to the acceleration.

MEMS accelerometers are typically implemented into systems having many electronic devices. Each device may emit electromagnetic interference waves, and, if the MEMS accelerometer is placed too close to another device, it may experience parasitic capacitance from the device during operation. To minimize this phenomenon, a cap is typically used to enclose the proof mass, and the cap is grounded to the wafer via bond wires.

MEMS accelerometers are increasingly becoming smaller, thus, bond wires having fine and ultra-fine pitches and decreased diameters are typically used; however, using these bond wires may have certain drawbacks. For example, the decreased pitch and diameter may cause difficulties in handling and bonding the bond wires. In particular, the bond wires may unintentionally short to other conductive structures of the MEMS accelerometer. Additionally, attaching bond wires to the components is a relatively expensive process.

Accordingly, it is desirable to provide a process for manufacturing a MEMS accelerometer that is relatively inexpensive and simple to implement and that does not unintentionally short to other conductive structures. In addition, it is desirable for the process not to employ additional manufacturing equipment. Furthermore, other desirable features and characteristics of the present invention will become apparent from the subsequent detailed description and the appended claims, taken in conjunction with the accompanying drawings and the foregoing technical field and background.

### BRIEF DESCRIPTION OF THE DRAWINGS

The present invention will hereinafter be described in conjunction with the following drawing figures, wherein like numerals denote like elements, and

FIG. 1 is a cross-sectional view of an exemplary MEMS device;

FIG. 2 is a top view of the exemplary MEMS sensor depicted in FIG. 1;

FIG. 3 is a cross-sectional view of another exemplary MEMS device;

FIG. 4 is a flow diagram depicting an exemplary method for manufacturing the exemplary MEMS devices illustrated in FIGS. 1 and 2;

FIG. 5 is a cross-sectional view of an exemplary substrate that may be used in the method depicted in FIG. 4;

FIG. 6 is a top view of the exemplary substrate shown in FIG. 5; and

FIG. 7 is a cross-sectional view of the exemplary substrate of FIG. 5 during another step of the exemplary method depicted in FIG. 4;

FIG. 8 is a cross-sectional view of the exemplary substrate of FIG. 5 during another step of the exemplary method depicted in FIG. 4;

FIG. 9 is a cross-sectional view of the exemplary substrate of FIG. 5 during another step of the exemplary method depicted in FIG. 4; and

FIG. 10 is a cross-sectional view of the exemplary substrate of FIG. 5 during another step of the exemplary method depicted in FIG. 4.

### DETAILED DESCRIPTION OF THE INVENTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description. In this regard, although the invention is depicted and described in the context of an accelerometer, it will be appreciated that the invention at least could be used for any one of numerous devices that include a proof mass movably suspended above a substrate surface or any microelectromechanical systems (“MEMS”) device that may need protection from electromagnetic interference.

Turning now to the description, FIG. 1 is a cross-sectional view of an exemplary MEMS device 100. MEMS device 100 is an inertial sensor, such as an accelerometer, and includes a field region 102 and a sensor region 104 formed on a wafer 106. Wafer 106 may be any one of numerous types of conventionally-used wafers. For example, and as depicted in FIG. 1, wafer 106 may be an SOI (“silicon-on-insulator”) wafer. In such case, wafer 106 generally includes a handle layer 108, an active layer 112, and a sacrificial layer 114 disposed between handle layer 108 and active layer 112. Field region 102 and sensor region 104 are both formed in active layer 112. Field region 102 is a region of active layer 112 that remains affixed to handle layer 108, via sacrificial layer 114. Conversely, sensor region 104, while being coupled to field region 102, is also partially released from handle layer 108. In particular, sensor region 104 is partially undercut by removing portions of sacrificial layer 114 below sensor region 104. This undercut forms a release trench 116 that releases portions of sensor region 104 from handle layer 108. The released portions of sensor region 104 are thus suspended above wafer 106.

Sensor region 104 includes a plurality of sensor elements, which may vary depending, for example, on the particular MEMS device 100 being implemented. However, in the depicted embodiment, in which MEMS device 100 is an accelerometer, the sensor elements include a suspension spring 122, a structure 124, which in this case is a seismic mass, a moving electrode 126, and a fixed electrode 128. Suspension spring 122 resiliently suspends seismic mass 124 and moving electrode 126 above handle layer 108 and is preferably configured to be relatively flexible. Suspension spring 122, seismic mass 124, and moving electrode 126 each overlie release trench 116 and are thus, all released from and suspended above wafer 106. Fixed electrode 128, however, remains affixed to wafer 106 via, for example, sacrificial layer 114.

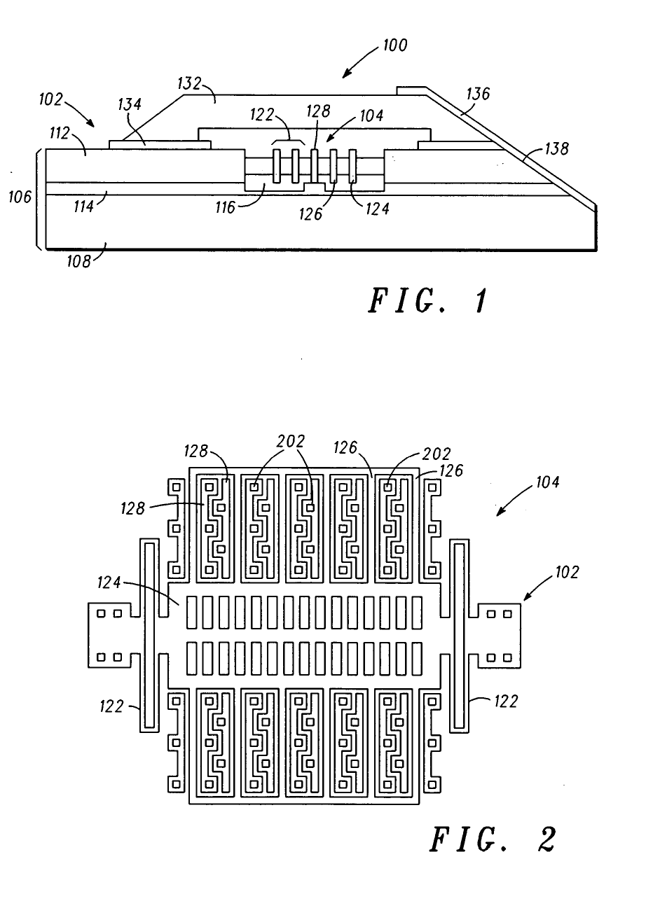

For clarity and ease of illustration, it will be appreciated that the sensor region 104 is depicted in FIG. 1 to include only a single suspension spring 122, a single moving electrode 126, and a single fixed electrode 128. However, in a particular physical implementation, which is shown more clearly in FIG. 2, and which will now be described in more detail, the sensor region 104 includes a pair of suspension springs 122, a plurality of moving electrodes 126, and a plurality of fixed electrodes 128. Suspension springs 122 are each coupled between field region 102 and seismic mass 124 and, as was previously noted, resiliently suspend seismic mass 124, when released, above wafer 106. Moving electrodes 126 are each coupled to seismic mass 124, and thus are also, when released, suspended above wafer 106. As FIG. 2 also shows, moving electrodes 126 are each disposed between two fixed electrodes 128. Fixed electrodes 128, as was noted above, are not released. Rather, fixed electrodes 128 remain anchored to wafer 106, via a plurality of anchors 202.

Turning back to FIG. 1, to reduce the presence of parasitic capacitance during the operation of MEMS device 100, a protective cap 132 and an interconnect 136 are included. Protective cap 132 is coupled to wafer 106, and extends over at least sensor region 104 to provide physical protection thereof. Preferably, protective cap 132 is partially spaced-apart from sensor region 104 to allow at least a portion of sensor region 104 to move. Protective cap 132 and wafer 106 may be coupled to each other in any one of numerous manners. For example, in the depicted embodiment, protective cap 132 is coupled to field region 102 via a cap anchor 134. Cap anchor 134 may be any one of numerous suitable devices for sealingly coupling protective cap 132 to wafer 106, such as, for example, a frit seal. Alternatively, protective cap 132 may be coupled to one or more non-movable portions of sensor region 104, such as one or more fixed electrodes 128.

During operation, when MEMS device 100 experiences acceleration, seismic mass 124 will move a distance that is proportional to the magnitude of the acceleration being experienced. Moving electrode 126 is connected to seismic mass 124, and thus move the same distance as seismic mass 124. Moving electrode 126 and fixed electrode 128 together form a variable differential capacitor. Thus, when MEMS device 100 experiences an acceleration, moving electrode 126 may move toward or away from fixed electrode 128. The distance that the moving electrode 126 moves will result in a proportional change in capacitance between fixed electrode 126 and moving electrode 128. This change in capacitance may be measured and used to determine the magnitude of the acceleration.

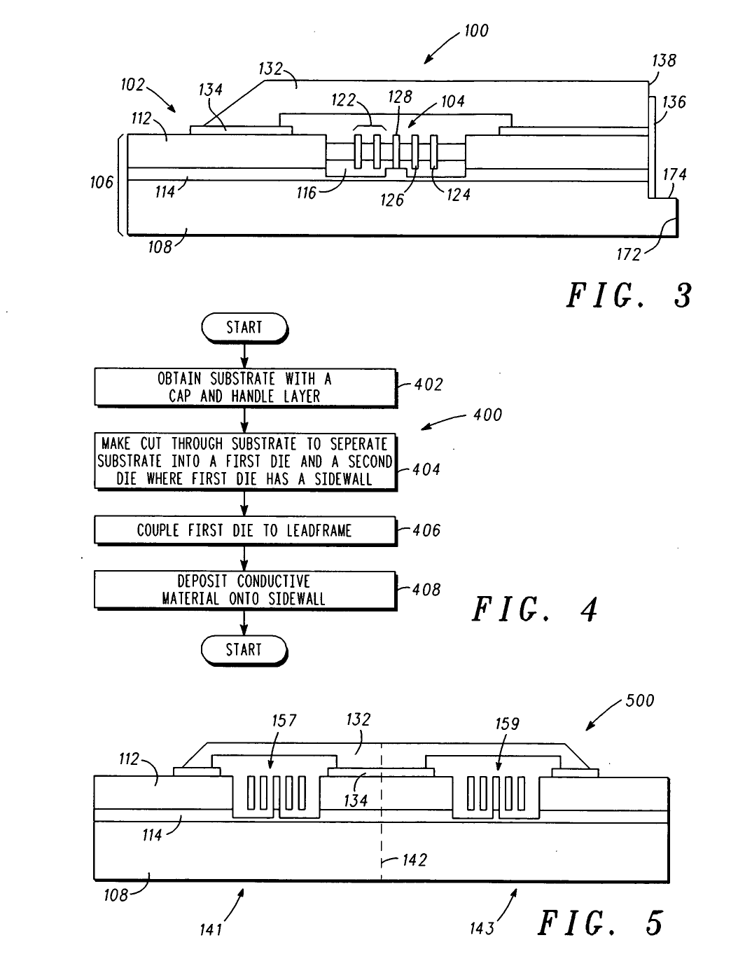

Interconnect 136 grounds protective cap 132 to handle layer 108 to prevent parasitic capacitance from interfering with the above-mentioned capacitance measurement. Preferably, interconnect 136 is coupled to a sidewall 138 that is defined by edges of active layer 112, sacrificial layer 114, protective cap 132, and cap anchor 134. Sidewall 138 may be beveled, as shown in FIG. 1, or, alternatively, may be a substantially straight or vertical cut. In a straight configuration, such as in the embodiment shown in FIG. 3, sidewall 138 may be joined with a second wall 172 via a shelf 174 formed therebetween that is configured to retain interconnect 136 on sidewall 138. Interconnect 136 is adhered to sidewall 138 such that at least protective cap 132 and handle layer 108 are electrically coupled. Alternatively, interconnect 136 may extend beyond sidewall 138 and may cover other portions of protective cap 132, such as a top portion.

Interconnect 136 may be made of any one of a number of conductive materials. For example, interconnect 136 may comprise a metal, and may be a single layer of metal, such as aluminum, or may be a double layer of metal, such as, titanium or chromium and aluminum. It will be appreciated that other suitable metals may be employed as well. In another example, interconnect 136 is a conductive epoxy.

Turning to FIG. 4, a flow diagram of an exemplary method 400 for manufacturing MEMS device 100 is depicted. First, a substrate having at least a protective cap over a handle layer is obtained (step 402). Then, a cut is made through the substrate to separate the substrate into a first die and a second die, where the first die has a sidewall (step 404). The first die is then coupled to a leadframe (step 406). Next, a conductive material is deposited onto the sidewall (step 408).

Step 402 may be performed using any one of numerous conventional techniques. For example, a suitable substrate may be obtained off-the-shelf, or alternatively, may be manufactured. FIG. 5 illustrates a cross-sectional view of an exemplary suitable substrate 500. Substrate 500 includes handle layer 108, sacrificial layer 114 disposed over handle layer 108, active layer 112 disposed over sacrificial layer 114, sensor regions 157 and 159 formed in active layer 112, and protective cap 132. Cap anchor 134 is disposed between protective cap 132 and active layer 112. Substrate 500 also includes a first die section 141 and a second die section 143 defined by a dotted line 142 that each includes one of sensor regions 157 and 159. Although two die sections 141 and 143 are illustrated in FIG. 5, it will be appreciated that more are typically formed in a substrate. For example, as shown in a top view of substrate 500 provided in FIG. 6, substrate 500 may include a plurality of die sections 141, 143, 145, 147, 149, 151, 153, and 155 which include a plurality of sensor regions 157, 159, 161, 163, 165, 167, 169, and 171 and bond pads 173, 175, 177, 179, 181, 183, 185, and 187 formed thereon. Each die section 141, 143, 145, 147, 149, 151, 153, and 155 is defined in FIG. 6 by perpendicular intersecting dotted lines, e.g. lines 144 and 146. Although each die section 141, 143, 145, 147, 149, 151, 153, and 155 is shown as being rectangular, it will be appreciated that the die sections may have any other suitable shape, such as, for example, circular, ovular, pentagonal, hexagonal, septagonal, or the like.

Next, a cut is made through protective cap 132 and handle layer 108 to separate substrate 500 into a first die 148 and a second die 150, where first die 148 has sidewall 138 (step 404). In one exemplary embodiment, a cut is made along at least one of the dotted lines shown in FIG. 6, such as, for example, along dotted line 144 or along dotted line 146. Alternatively, if die sections 141, 143, 145, 147, 149, 151, 153, and 155 have shapes other than rectangular, the cut may be made in any non-active areas of die sections 141, 143, 145, 147, 149, 151, 153, and 155. It will be appreciated that any type of cut may be made through substrate 500 to separate first die 148 from second die 150, such as, for example, a straight cut or a bevel cut.

In one exemplary embodiment of step 404, a single bevel cut is made between first die section 141 and second die section 143 using a V-shaped blade. The blade may have a 60 degree bevel. In another exemplary embodiment, multiple cuts are made. For example, a first cut is first made, and then a second cut is made at an angle relative to the first cut to form a V-shaped trough. The angle between the first and second cuts is preferably about 60 degrees, however, any other angle may alternatively be suitable. Next, a straight cut is used to separate the first die 148 from the second die 150.

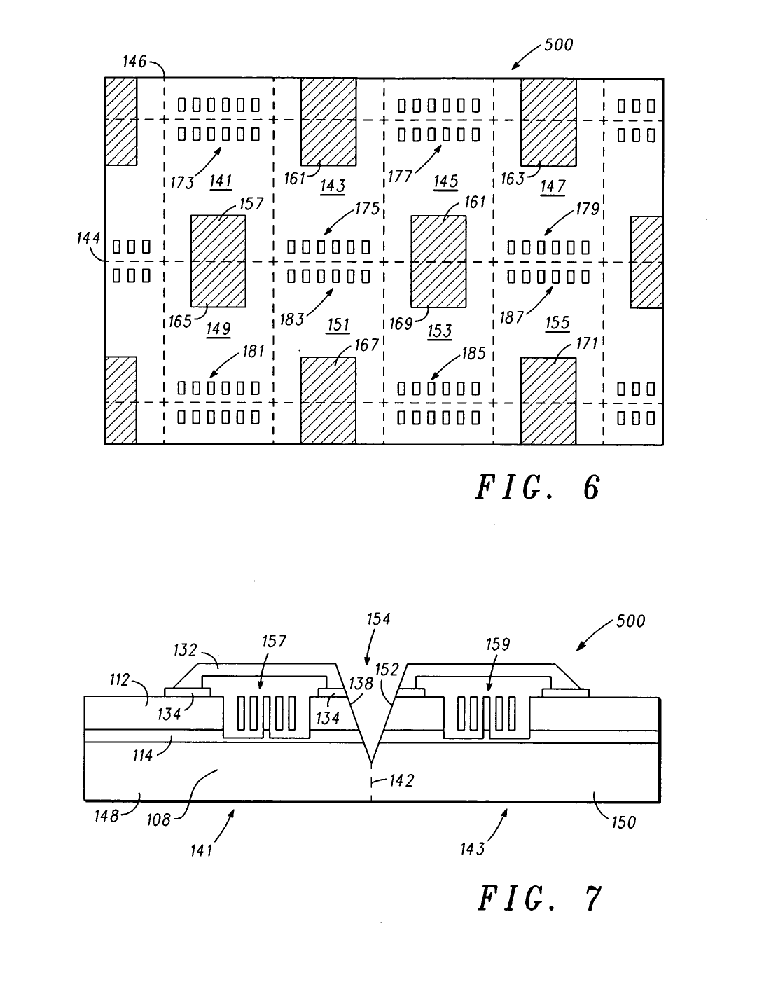

FIG. 7 shows one exemplary embodiment of substrate 500 including a bevel cut made by a V-shaped blade between a first die section 141 and a second die section 143. In this embodiment, the cut extends through protective cap 132, cap anchor 134, active layer 112, sacrificial layer 114, and handle layer 108. As depicted in FIG. 6, only a portion of handle layer 108 is cut so that first die section 141 and second die section 143 remain joined to one another. Each of protective cap 132, cap anchor 134, active layer 112, sacrificial layer 114, and handle layer 108 has exposed edges that together define a first sidewall 138 and a second sidewall 152. First and second sidewalls 138 and 152 form a trough 154.

Then, first die section 141 is singulated from second die section 143. Singulation may occur using any one of numerous conventional techniques, such as by sawing, and may be achieved using any type of cut, for example, a straight cut. In any event, substrate 500 is cut to separate die sections 141 and 143 into first die 148 and second die 150. Preferably, the cut is made through a section of trough 154. For example, the cut may be placed between first sidewall 138 and second sidewall 152.

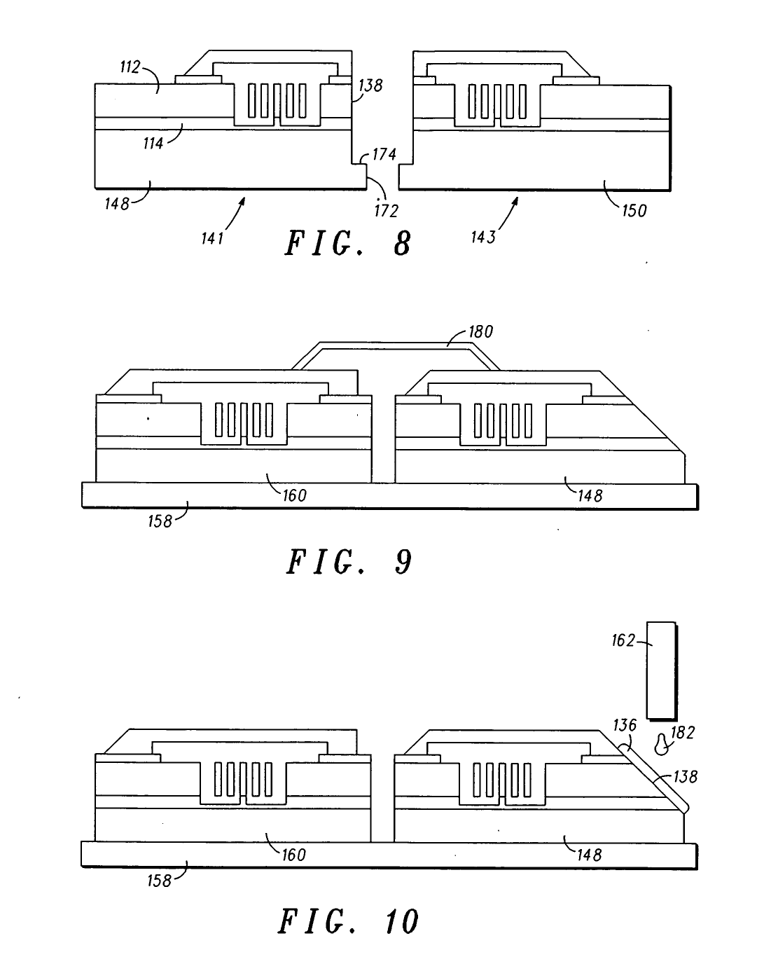

In another exemplary embodiment of step 404, straight cuts are made between first die section 141 and second die section 143. In one embodiment, a single cut is made through handle layer 108 to separate first die section 141 from second die section 143. In another exemplary embodiment of step 404, multiple cuts are made between first and second die sections 141 and 143. Here, as shown in FIG. 8, first, a substantially vertical cut is made through protective cap 132 and a first portion of handle layer 108 to form first sidewall 138. Then, a second cut is made laterally through a second portion of handle layer 108 to form shelf 174. A third cut is then made substantially vertically through the remaining third portion of handle layer 108 to separate the first die section 141 from the second die section 143, thereby forming second wall 172 on first die section 141. It will be appreciated that any one of numerous other manners by which to singulate die sections 141 and 143 and configurations of walls 138 and 172 may be alternatively incorporated.

After die sections 141 and 143 are singulated, first die 148 is mounted to a leadframe 158, as shown in FIG. 9 (step 406). It will be appreciated that any leadframe to which dies are conventionally mounted may be used. Moreover, first die 148 may be mounted to leadframe 158 by any one of a number of manners, such as, for example, by solder, epoxy, or glue. Additionally, first die 148 may be further processed. For example, first die 148 maybe wirebonded to the leadframe 158. Alternatively, if leadframe 158 includes another die, such as a control die 160, first die 148 may be wirebonded to die 160 via wires 180, as shown in FIG. 9.

Next, a conductive material 182 is deposited onto sidewall 138 of first die 148 to form interconnect 136 (step 408). Conductive material 182 may be any material having conductive properties, such as, for example, a conductive epoxy, a metal, or any other material. Preferably, conductive material 182 is capable of grounding protective cap 132 to handle layer 108.

Conductive material 182 may be deposited onto sidewall 138 in any conventional manner. In one exemplary embodiment, as shown in FIG. 10, a dispenser 162, such as a dispensing needle, is coupled to a non-illustrated conductive material source. Dispenser 162 then deposits conductive material 182 onto sidewall 138. Preferably, dispenser 162 is configured to deposit a sufficient amount of conductive material 182 on sidewall 138 so as to electrically couple protective cap 132 to handle layer 108.

After step 408, first die 148 and leadframe 158 may be further processed. For example, first die 148 and leadframe 158 may undergo a reflow process to ensure the coupling of first die 148 to leadframe 158. Alternatively, first die 148 may undergo an encapsulation process during which an appropriate molding material is deposited over first die 148.

Methods have been provided for forming a micro-electromechanical systems (“MEMS”) device from a substrate comprising a handle layer and a cap overlying the handle layer. In one exemplary embodiment, the method includes cutting through the substrate to separate the substrate into a first die and a second die, the first die having a first sidewall, and depositing a conductive material onto the first sidewall to electrically couple the cap to the handle layer. The step of cutting may comprise making a first bevel cut through the cap and at least a portion of the handle layer to form the first sidewall. Alternatively, the step of cutting may further comprise making a second bevel cut through the cap and at least a portion of the handle layer at an angle relative to the first sidewall to form a second sidewall. In another alternative, the step of cutting further comprises making a straight cut between the first and second sidewalls to separate the substrate into the first and second dies. In still another alternative, the step of cutting comprises making a straight cut through the cap and a first portion of the handle layer to form the first sidewall. In still yet another embodiment, the step of cutting further comprises cutting a second portion of the handle layer to form a second sidewall and a shelf between the first and the second sidewalls. Alternatively, the step of cutting further comprises cutting a third portion of the handle layer to separate the first die from the second die.

In another exemplary embodiment, the step of depositing a conductive material comprises dispensing a conductive material onto the first sidewall. In one exemplary embodiment, the conductive material is conductive epoxy. In still another embodiment, the method further comprises die bonding the first die to a leadframe, before the step of depositing. In another embodiment, the method further comprises wire bonding the first die to the leadframe, before the step of depositing.

In another exemplary embodiment, the method includes making a first bevel cut through the cap and at least a portion of the handle layer to form the first sidewall, making a second bevel cut through the cap and at least a portion of the handle layer at an angle relative to the first sidewall to form a second sidewall, making a straight cut between the first and second sidewalls to separate the substrate into the first and second dies, the first die including the first sidewall and the second die including the second sidewall, and depositing a conductive material onto the first sidewall to electrically couple the cap to the handle layer. The step of depositing a conductive material may comprise dispensing a conductive material onto the first sidewall. The conductive material may be conductive epoxy. The method may further comprise die bonding the first die to a leadframe, before the step of depositing. The method may further comprise wire bonding the first die to the leadframe, before the step of depositing.

In still another exemplary embodiment, the method includes the steps of making a straight cut through the cap and a first portion of the handle layer to form a first sidewall, cutting a second portion of the handle layer to form a second sidewall and a shelf between the first and the second sidewalls, cutting a third portion of the handle layer to separate a first die from a second die, and depositing a conductive material onto the first sidewall to electrically couple the cap to the handle layer. The step of depositing a conductive material may comprise dispensing a conductive material onto the first sidewall. The method may further comprise die bonding the first die to a leadframe, before the step of depositing. Alternatively, the method may also further comprise wire bonding the first die to the leadframe, before the step of depositing.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method of forming a micro-electromechanical systems (“MEMS”) device from a substrate comprising a handle layer and a cap overlying the handle layer, the method comprising:
cutting through the substrate to separate the substrate into a first die and a second die, the first die having a first sidewall; and
depositing a conductive material onto the first sidewall to electrically couple the cap to the handle layer.

2. The method of claim 1, wherein the step of cutting comprises making a first bevel cut through the cap and at least a portion of the handle layer to form the first sidewall.

3. The method of claim 2, wherein the step of cutting further comprises making a second bevel cut through the cap and at least a portion of the handle layer at an angle relative to the first sidewall to form a second sidewall.

4. The method of claim 3, wherein the step of cutting further comprises making a straight cut between the first and second sidewalls to separate the substrate into the first and second dies.

5. The method of claim 1, wherein the step of cutting comprises making a straight cut through the cap and a first portion of the handle layer to form the first sidewall.

6. The method of claim 5, wherein the step of cutting further comprises cutting a second portion of the handle layer to form a second sidewall and a shelf between the first and the second sidewalls.

7. The method of claim 6, wherein the step of cutting further comprises cutting a third portion of the handle layer to separate the first die from the second die.

8. The method of claim 1, wherein the step of depositing a conductive material comprises dispensing a conductive material onto the first sidewall.

9. The method of claim 8, wherein the conductive material is conductive epoxy.

10. The method of claim 1, further comprising die bonding the first die to a leadframe, before the step of depositing.

11. The method of claim 1, further comprising wire bonding the first die to the leadframe, before the step of depositing.

12. A method of forming a micro-electromechanical systems (“MEMS”) device from a substrate comprising a handle layer and a cap overlying the handle layer, the method comprising:
making a first bevel cut through the cap and at least a portion of the handle layer to form the first sidewall;
making a second bevel cut through the cap and at least a portion of the handle layer at an angle relative to the first sidewall to form a second sidewall;
making a straight cut between the first and second sidewalls to separate the substrate into the first and second dies, the first die including the first sidewall and the second die including the second sidewall; and
depositing a conductive material onto the first sidewall to electrically couple the cap to the handle layer.

13. The method of claim 12, wherein the step of depositing a conductive material comprises dispensing a conductive material onto the first sidewall.

14. The method of claim 13, wherein the conductive material is conductive epoxy.

15. The method of claim 12, further comprising die bonding the first die to a leadframe, before the step of depositing.

16. The method of claim 12, further comprising wire bonding the first die to the leadframe, before the step of depositing.

17. A method of forming a micro-electromechanical systems (“MEMS”) device from a substrate comprising a handle layer and a cap overlying the handle layer, the method comprising:
making a straight cut through the cap and a first portion of the handle layer to form a first sidewall;
cutting a second portion of the handle layer to form a second sidewall and a shelf between the first and the second sidewalls;
cutting a third portion of the handle layer to separate a first die from a second die; and
depositing a conductive material onto the first sidewall to electrically couple the cap to the handle layer.

18. The method of claim 17, wherein the step of depositing a conductive material comprises dispensing a conductive material onto the first sidewall.

19. The method of claim 17, further comprising die bonding the first die to a leadframe, before the step of depositing.

20. The method of claim 17, further comprising wire bonding the first die to the leadframe, before the step of depositing.
